(19) United States
(12) Patent Application Publication
(10) Pub. No.: US 2006/0249753 A1
(43) Pub. Date: Nov. 9, 2006

(54) High-density nonvolatile memory array fabricated at low temperature comprising semiconductor diodes

(75) Inventors: S. Brad Herner, San Jose, CA (US); Samuel V. Dunton, San Jose, CA (US)

Correspondence Address: MATRIX SEMICONDUCTOR, INC., 3230 SCOTT BOULEVARD, SANTA CLARA, CA, 95054, US

(73) Assignee: Matrix Semiconductor, Inc., Santa Clara, CA (US)

(21) Appl. No.: 11/125,606

(22) Filed: May 9, 2005

(51) Int. Cl. H01L 27/10; H01L 21/82

(52) U.S. Cl. 257/202; 438/128; 438/131; 257/209

(57) ABSTRACT

A memory cell is described suitable for use in a high-density monolithic three dimensional memory array. In preferred embodiments of the memory cell, a semiconductor junction diode formed of germanium or a germanium alloy which can be crystallized at relatively low temperature is formed disposed between conductors. The use of a low-temperature material allows the conductors to be formed of copper or aluminum, both low-resistivity materials that provide adequate current at very small feature size, allowing for a highly dense stacked array.

### RELATED APPLICATION

This application is related to Herner et al., U.S. application Ser. No. ______, “Rewriteable Memory Cell Comprising a Diode and a Resistance-Switching Material,” (attorney docket number MA-146), hereinafter the ______ application, which is assigned to the assignee of the present invention, filed on even date herewith and hereby incorporated by reference in its entirety.

### BACKGROUND OF THE INVENTION

The invention relates to a very high-density nonvolatile memory array comprising germanium or germanium-alloy diodes.

In conventional semiconductor devices, memory cells are fabricated in a monocrystalline silicon wafer substrate, with conductive wiring providing electrical connection to the memory cells. In general these conductors can be formed after the array is formed, and thus need not be subjected to the temperatures required to form the memory cells themselves. Specifically, top metal conductors need not be subjected to the temperatures experienced during, for example, deposition and crystallization of polycrystalline silicon (in this discussion polycrystalline silicon will be called polysilicon), which usually exceeds about 550 degrees C. (Polysilicon is often used in memory elements, such as control gates and floating gates.) Thus metals that cannot tolerate high processing temperatures, such as aluminum and copper, can successfully be used in conductors in conventional two-dimensional semiconductor devices. Aluminum and copper are both very low-resistivity materials, desirable for use in conductors.

In monolithic three dimensional memory arrays such as those described in Johnson et al., U.S. Pat. No. 6,034,882, “Vertically stacked field programmable nonvolatile memory and method of fabrication,” assigned to the assignee of the present invention and hereby incorporated by reference, multiple memory levels are formed stacked one atop another above a monocrystalline silicon wafer substrate.

In a monolithic three dimensional memory array, conductors formed as part of a first memory level must be able to tolerate the processing temperatures required to form every element of the memory cells in the next level and in all subsequently formed memory levels. If the memory cell includes deposited silicon which must be crystallized, then, using conventional deposition and crystallization techniques, conductors must be able to tolerate temperatures exceeding, for example, 550 degrees C.

Aluminum wiring tends to soften and extrude at temperatures above about 475 degrees C., and copper has even lower thermal tolerance. Thus in arrays like those of Johnson et al., materials that can survive higher processing temperatures have been preferred for use as conductors.

As memory arrays like those of Johnson et al. are scaled to smaller dimensions, the cross-sectional area of conductors shrink, increasing their resistance. There is a need, therefore, for a robust, low-cost method to make a high-density memory device comprising deposited semiconductor material at low temperature, allowing the use of low-resistance conductors.

### SUMMARY OF THE PREFERRED EMBODIMENTS

The present invention is defined by the following claims, and nothing in this section should be taken as a limitation on those claims. In general, the invention is directed to a non-volatile memory cell that can be fabricated in a high-density array, having germanium or germanium alloy diodes and conductors formed of low-resistivity material.

A first aspect of the invention provides for a method for forming a monolithic three dimensional memory array, the method comprising forming a first memory level above a substrate, the first memory level comprising a first plurality of memory cells, each first memory cell comprising semiconductor material; and monolithically forming a second memory level above the first memory level, wherein during formation of the monolithic three dimensional memory array, processing temperature during formation of the array does not exceed about 500 degrees C.

Another aspect of the invention provides for a monolithic three dimensional memory array comprising a) a first memory level comprising: i) a first plurality of bottom conductors, the first bottom conductors comprising a first aluminum layer or first copper layer; ii) a first plurality of pillar-shaped diodes above the first bottom conductors, the first diodes comprising germanium or a germanium alloy; and iii) a first plurality of top conductors above the first diodes, the first top conductors comprising a second aluminum layer or a second copper layer; and b) a second memory level monolithically formed above the first memory level.

Yet another aspect of the invention provides for a method for forming a first memory level, the method comprising: forming a first plurality of substantially parallel, substantially coplanar rail-shaped bottom conductors extending in a first direction, the first bottom conductors comprising copper or aluminum; forming a first plurality of diodes above the first bottom conductors, the first diodes comprising germanium or a germanium alloy; forming a first plurality of substantially parallel, substantially coplanar rail-shaped top conductors above the first diodes, the first top conductors, the first top conductors extending in a second direction different from the first direction, the first top conductors comprising copper or aluminum, wherein, during formation of the first memory level, processing temperature does not exceed 500 degrees C.

Another aspect of the invention provides for a nonvolatile one-time programmable memory cell comprising: a bottom conductor; a polycrystalline diode above the bottom conductor; and a top conductor above the diode, wherein, after the cell has been programmed, when about 1 volt is applied between the top conductor and the bottom conductor, a current flowing through the diode is at least about 100 microamps.

Still another aspect of the invention provides for a nonvolatile memory cell comprising: a bottom conductor comprising aluminum or copper; a pillar comprising a semiconductor material, wherein the semiconductor material is at least 20 atomic percent germanium; and a top conductor comprising aluminum or copper, wherein the pillar is disposed between the top conductor and the bottom conductor, and wherein the semiconductor material is formed in a high-resistance state, and, upon application of a programming voltage, converts to a diode in a low-resistance state.

A preferred embodiment of the invention provides for a monolithic three dimensional memory array comprising: a) a first memory level formed above a substrate, the first memory level comprising a plurality of memory cells, each memory cell comprising: i) a bottom conductor comprising an aluminum alloy; ii) a pillar comprising a semiconductor material, wherein the semiconductor material is at least 20 atomic percent germanium; and iii) a top conductor comprising an aluminum alloy, wherein the pillar is disposed between the top conductor and the bottom conductor, and wherein the semiconductor material is formed in a high-resistance state, and, upon application of a programming voltage, converts to a diode in a low-resistance state; and b) a second memory level monolithically formed above the first.

Another preferred embodiment of the invention provides for a monolithic three dimensional memory array comprising: a) a first memory level formed above a substrate, the first memory level comprising: i) a bottom conductor comprising copper, the bottom conductor formed by a damascene method; ii) a pillar comprising a semiconductor material, wherein the semiconductor material is at least 20 atomic percent germanium; and iii) a top conductor comprising copper, the top conductor formed by a damascene method, wherein the pillar is disposed between the top conductor and the bottom conductor, and wherein the semiconductor material is formed in a high-resistance state, and, upon application of a programming voltage, converts to a diode in a low-resistance state; and b) a second memory level monolithically formed above the first.

A preferred aspect of the invention provides for a method for forming a monolithic three dimensional memory array, the method comprising: a) forming a first memory level above a substrate by a method comprising: i) forming a first plurality of substantially parallel, substantially coplanar bottom conductors, the first bottom conductors comprising copper or an aluminum alloy; ii) forming a first plurality of diodes above the first bottom conductors, the first diodes comprising germanium or a germanium alloy; and iii) forming a first plurality of substantially parallel, substantially coplanar top conductors above the first diodes, the first top conductors comprising copper or an aluminum alloy; and b) monolithically forming a second memory level above the first memory level.

Each of the aspects and embodiments of the invention described herein can be used alone or in combination with one another.

The preferred aspects and embodiments will now be described with reference to the attached drawings.

### BRIEF DESCRIPTION OF THE DRAWINGS

FIG. 1 is perspective view of a memory cell formed according to the '470 application.

FIG. 2 is a perspective view of a memory level comprising cells like the cell of FIG. 1.

FIG. 3 is a perspective view of a one-time programmable nonvolatile memory cell formed according to an embodiment of the present invention.

FIGS. 4a-4c are cross-sectional views illustrating stages in formation of a monolithic three dimensional memory array formed according to a preferred embodiment of the present invention.

FIGS. 5a-5d are cross-sectional views illustrating stages in formation of a monolithic three dimensional memory array formed according to another preferred embodiment of the present invention.

### DETAILED DESCRIPTION OF THE PREFERRED EMBODIMENTS

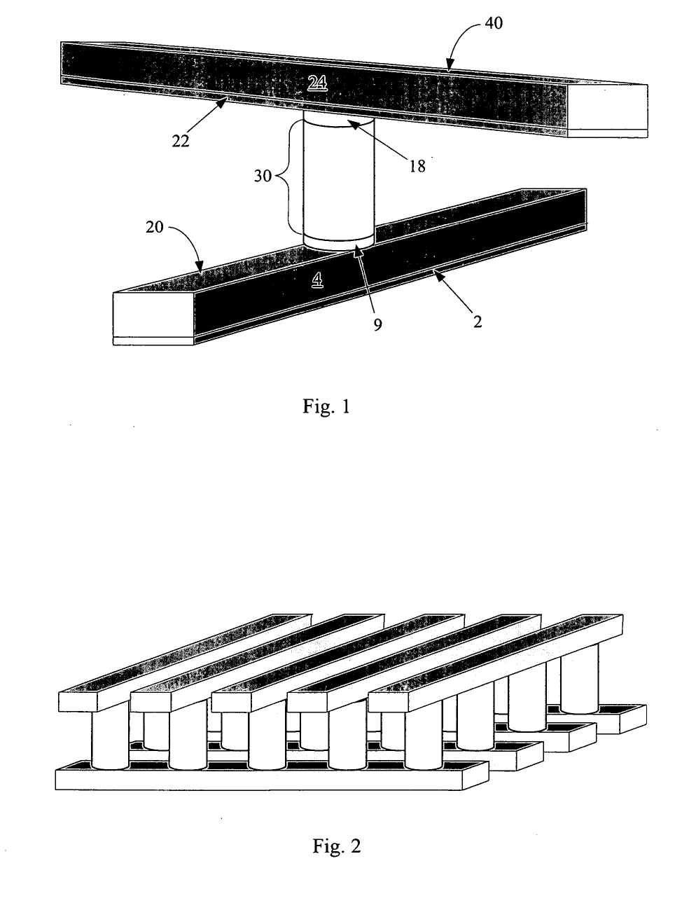

FIG. 1 shows a memory cell taught in Herner et al., U.S. application Ser. No. 10/326,470, hereinafter the '470 application, since abandoned, and hereby incorporated by reference. The '470 application describes fabrication and use of a monolithic three dimensional memory array comprising such cells formed above a substrate, preferably of monocrystalline silicon. Related memory arrays, and their use and methods of manufacture, are taught in Herner et al., U.S. patent application Ser. No. 10/955,549, “Nonvolatile Memory Cell Without a Dielectric Antifuse Having High- and Low-Impedance States,” filed Sep. 29, 2004 and hereinafter the '549 application; in Herner et al., U.S. patent application Ser. No. 11/015,824, “Nonvolatile Memory Cell Comprising a Reduced Height Vertical Diode,” filed Dec. 17, 2004, and hereinafter the '824 application; and in Herner et al., U.S. patent application Ser. No. 10/954,577, “Junction Diode Comprising Varying Semiconductor Compositions,” filed Sep. 29, 2004, and hereinafter the '577 application, all owned by the assignee of the present application and hereby incorporated by reference.

Referring to FIG. 1, in preferred embodiments of the '470 application a polysilicon diode 30 is disposed between bottom conductor 20 and top conductor 40, and is separated from top conductor 40 by a dielectric rupture antifuse 18, typically a thin oxide layer. The cell is formed in an initial high-resistance state, and when a read voltage is applied between bottom conductor 20 and top conductor 40, little or no current flows between them. Upon application of a programming voltage, however, the cell is permanently converted to a low-resistance state. In this low-resistance state, when the read voltage is applied between bottom conductor 20 and top conductor 40 a reliably detectable current flows. The initial high-resistance state may correspond to, for example, a data “0” while the programmed low-resistance state corresponds to a data “1”.

The change from high-resistance to low-resistance state results from at least two changes. The dielectric rupture antifuse 18 suffers dielectric breakdown and irreversibly ruptures, become conductive through a rupture path formed through antifuse 18. In addition, as described more fully in the '549 application, the semiconductor material of the diode itself is converted from a high-resistance state to a low-resistance state. The diode 30 is polycrystalline before programming. After a programming voltage is applied, the polysilicon diode 30 is more conductive than prior to application of the programming voltage.

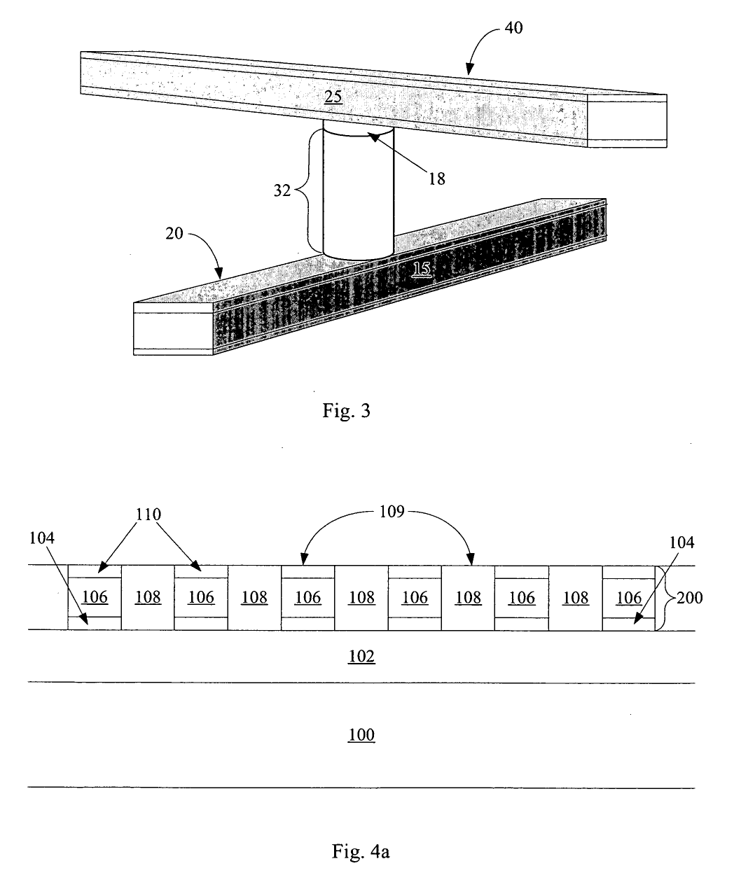

In preferred embodiments of the '470, '549, '824 and '577 applications, bottom conductor 20 and top conductor 40 comprise titanium nitride adhesion layers 2 and 22 and tungsten layers 4 and 24. A titanium nitride barrier layer 9 separates the polysilicon of diode 30 from tungsten layer 4. A plurality of such top and bottom conductors, with intervening diodes and antifuses, can be fabricated in a cross-point array, forming a first memory level, an exemplary portion of which is shown in FIG. 2.

The memory cell of FIG. 1 is highly effective for a wide range of dimensions. As the design is scaled to ever smaller dimensions, however, the cross-sectional areas of bottom conductor 20 and top conductor 40 decrease, and the resistance of the conductors increases. Compensating for decreasing width by increasing thickness quickly becomes impractical, as high-aspect ratio features are difficult to reliably pattern and etch and high-aspect ratio gaps are difficult to fill with dielectric. At very small feature size, tungsten conductors may be too highly resistive for successful device performance.

It would be desirable to use a low-resistivity material to form the top and bottom conductors. As noted earlier, however, the crystallization of polysilicon diode 30 is conventionally performed at temperatures incompatible with the use of aluminum or copper.

Decades ago silicon, rather than germanium, became the standard semiconductor material used in semiconductor integrated circuits. This is in large part due to the fact that silicon, when oxidized, forms silicon dioxide, a high-quality dielectric material widely used whenever a dielectric is required, including as an interlevel dielectric, field oxide, gap fill material, and gate dielectrics, among many other uses. There has been relatively little commercialization of monocrystalline germanium devices, and still less of devices using polycrystalline germanium.

In the present invention, polycrystalline diodes are formed of germanium or germanium-rich alloys. Crystallization of germanium at temperatures as low as about 350 degrees C. is described in Edelman et al., “Initial Crystallization Stage of Amorphous Germanium Films,” J. Appl. Phys., 5153 (1992). Crystallization below about 475 degrees C. allows the use of aluminum conductors, while lower temperatures allow the use of copper conductors. These low-resistivity metals form low-resistance conductors, which can be formed with reduced cross-section. Reducing width and aspect ratio allows for higher density in a memory array.

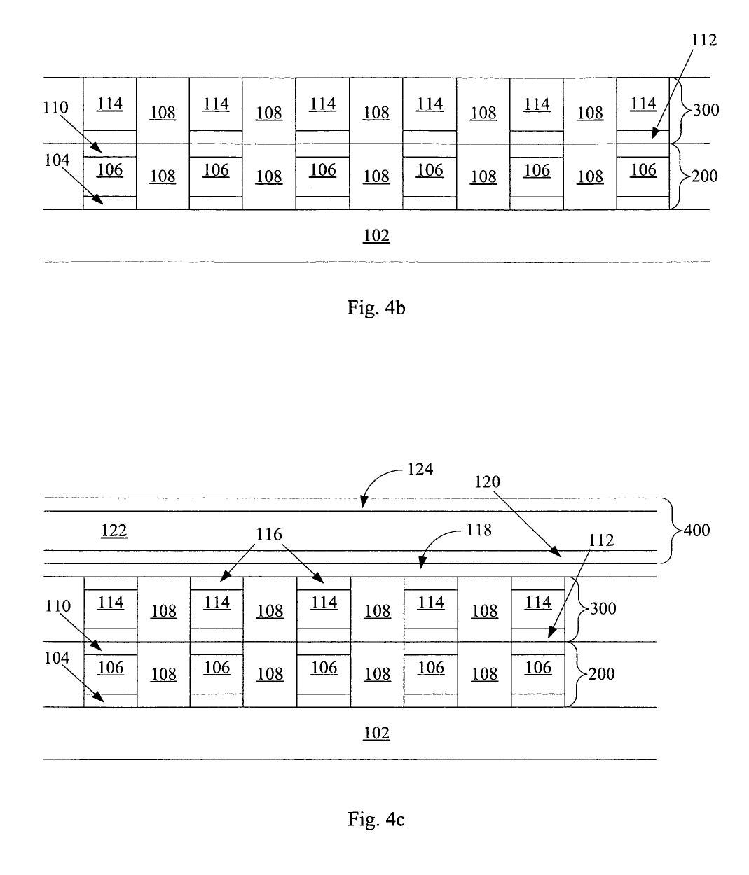

FIG. 3 shows a memory cell formed according to the present invention. In this embodiment bottom conductor 20 and top conductor 40 include aluminum layers 15 and 25, respectively; in alternate embodiments the conductors comprise copper. Diode 32 is a p-i-n diode formed of germanium or a germanium alloy. The germanium alloy is preferably at least 20 atomic percent germanium, preferably at least 50 atomic percent germanium, and in preferred embodiments is at least 80 or at least 90 atomic percent atomic germanium. A dielectric rupture antifuse 18 is arranged in series with diode 32 between the conductors. Dielectric rupture antifuse 18 can be formed of any appropriate dielectric material, such as an oxide, nitride, or oxynitride.

Use of germanium or a germanium-rich alloy rather than silicon allows the crystallization temperature of the diode to be reduced to as low as about 350 degrees C. at anneal times that remain practical for large-scale production.

Two detailed examples will be provided, each of a different monolithic three dimensional memory array formed according to the present invention. The first embodiment will describe use of aluminum conductors, while the second will describe use of copper conductors. For clarity many details, including steps, materials, and process conditions, will be included. It will be understood that this example is non-limiting, and that these details can be modified, omitted, or augmented while the results fall within the scope of the invention. Specifically, teachings of the '470, '549, '824, '577 and other incorporated applications and patents may be relevant to formation of a memory according to the present invention. For simplicity, not all of the details of the incorporated applications and patents will be included, but it will be understood that no teaching of these applications or patents is intended to be excluded.

### EXAMPLE

### Aluminum Conductors

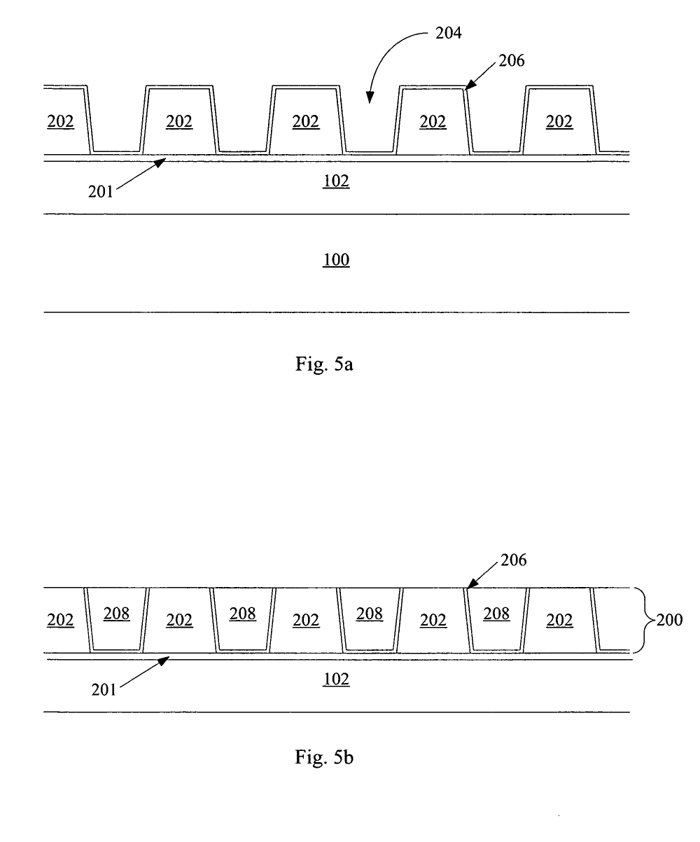

Turning to FIG. 4a, formation of the memory begins with a substrate 100. This substrate 100 can be any semiconducting substrate as known in the art, such as monocrystalline silicon, IV-IV compounds like silicon-germanium or silicon-germanium-carbon, III-V compounds, II-VII compounds, epitaxial layers over such substrates, or any other semiconducting material. The substrate may include integrated circuits fabricated therein.

An insulating layer 102 is formed over substrate 100. The insulating layer 102 can be silicon oxide, silicon nitride, high-dielectric film, Si—C—O—H film, or any other suitable insulating material.

The first conductors 200 are formed over the substrate 100 and insulator 102. An adhesion layer 104 may be included between the insulating layer 102 and the conducting layer 106 to help the conducting layer 106 adhere. A preferred material for adhesion layer 104 is titanium nitride, though other materials may be used, or this layer may be omitted. Adhesion layer 104 can be deposited by any conventional method, for example by sputtering.

The thickness of adhesion layer 104 can range from about 20 to about 500 angstroms, and is preferably between about 100 and about 400 angstroms, most preferably about 200 angstroms. Note that in this discussion, “thickness” will denote vertical thickness, measured in a direction perpendicular to substrate 100.

The next layer to be deposited is conducting layer 106. In the present embodiment, conducting layer 106 is aluminum or an aluminum alloy, though in less preferred embodiments, any conducting material known in the art, such as doped semiconductor, metals such as tungsten, or metal silicides may be used. The thickness of conducting layer 106 can depend, in part, on the desired sheet resistance and therefore can be any thickness that provides the desired sheet resistance. In one embodiment, the thickness of conducting layer 106 can range from about 500 to about 3000 angstroms, preferably about 1000 to about 2000 angstroms, most preferably about 1200 angstroms.

Another layer 110, preferably of titanium nitride, is deposited on conducting layer 106. This layer may be about the same thickness as adhesion layer 104. An antireflective coating may be used. Titanium nitride layer 110 will serve as a barrier layer between aluminum layer 106 and the germanium or germanium-rich alloy of the diodes yet to be formed.

Once all the layers that will form the conductor rails have been deposited, the layers will be patterned and etched using any suitable masking and etching process to form substantially parallel, substantially coplanar conductors 200, shown in FIG. 4a in cross-section. In one embodiment, photoresist is deposited, patterned by photolithography and the layers etched, and then the photoresist removed, using standard process techniques such as “ashing” in an oxygen-containing plasma, and strip of remaining polymers formed during etch in a conventional liquid solvent such as those formulated by EKC.

In a repeating pattern, pitch is the distance between a feature and the next recurrence of the same feature. In a plurality of substantially parallel lines like conductors 200, for example, the pitch of conductors 200 is the distance from the center of one line to the center of the next line. Conductors 200 may be formed at any desired pitch, but the pitch of conductors 200 is preferably no more than 180 nm, more preferably no more than about 150 nm, still more preferably no more than about 120 nm, and most preferably no more than about 90 nm. The pitch of conductors 200 may be less than 90 nm.

Next a dielectric material 108 is deposited over and between conductor rails 200. Dielectric material 108 can be any known electrically insulating material, such as silicon oxide, silicon nitride, or silicon oxynitride. In a preferred embodiment, silicon dioxide is used as dielectric material 108. The silicon oxide can be deposited using any known process, such as chemical vapor deposition (CVD), or, for example, high-density plasma CVD (HDPCVD).

Finally, dielectric material 108 on top of conductor rails 200 is removed, exposing the tops of conductor rails 200 separated by dielectric material 108, and leaving a substantially planar surface 109. The resulting structure is shown in FIG. 4a. This removal of dielectric overfill to form planar surface 109 can be performed by any process known in the art, such as etchback or chemical-mechanical planarization (CMP). For example, the etchback techniques described in Raghuram et al., U.S. application Ser. No. 10/883,417, “Nonselective Unpatterned Etchback to Expose Buried Patterned Features,” filed Jun. 30, 2004 and hereby incorporated by reference in its entirety, can advantageously be used.

If this planarization step is performed by CMP, some thickness of titanium nitride layer 110, for example, about 600 angstroms, will be lost. In this case an extra sacrificial thickness of titanium nitride should be provided, such that preferably at least about 200 angstroms of titanium nitride remains after CMP.

To summarize, the bottom conductors are formed by a method comprising depositing an aluminum layer or a conductive stack comprising an aluminum layer; patterning and etching the aluminum layer or conductive stack to form the first bottom conductors; depositing a first dielectric material over and between the first bottom conductors; and planarizing to form a substantially planar surface coexposing the first bottom conductors and the first dielectric material.

Next, turning to FIG. 4b, vertical pillars will be formed above completed conductor rails 200. (To save space substrate 100 is omitted in FIG. 4b and subsequent figures; its presence will be assumed in this and subsequent figures.) Semiconductor material that will be patterned into pillars is deposited. The semiconductor material can be silicon, silicon-germanium, silicon-germanium-carbon, germanium, or other suitable IV-IV compounds, gallium arsenide, indium phosphide, or other suitable Ill-V compounds, zinc selinide, or other II-VII compounds, or a combination. In preferred embodiments, germanium alloys of any proportion of germanium, for example including at least 20, at least 50, at least 80, or at least 90 atomic percent germanium or pure germanium may be used. The present example will describe the use of pure germanium. The term “pure germanium” does not exclude the presence of conductivity-enhancing dopants or contaminants normally found in a typical production environment.

In preferred embodiments, the semiconductor pillar comprises a junction diode. The term junction diode is used herein to refer to a semiconductor device with the property of non-ohmic conduction, having two terminal electrodes, and made of semiconducting material which is p-type at one electrode and n-type at the other. Examples include p-n diodes and n-p diodes, which have p-type semiconductor material and n-type semiconductor material in contact, such as Zener diodes, and p-i-n diodes, in which intrinsic (undoped) semiconductor material is interposed between p-type semiconductor material and n-type semiconductor material.

In most preferred embodiments, the junction diode comprises a bottom heavily doped region of a first conductivity type and a top heavily doped region of a second conductivity type opposite the first. The middle region, between the top and bottom regions, is an intrinsic or lightly doped region of either the first or second conductivity type. Such a diode can be described as a p-i-n diode.

In this example, bottom heavily doped region 112 is heavily doped n-type germanium. In a most preferred embodiment, heavily doped region 112 is deposited and doped with an n-type dopant such as phosphorus by any conventional method, preferably by in situ doping, though doping may be by ion implantation instead. This layer is preferably between about 200 and about 800 angstroms thick.

Next the germanium that will form the remainder of the diode is deposited. In some embodiments a subsequent planarization step will remove some germanium, so an extra thickness is deposited. If the planarization step is performed using a conventional CMP method, about 800 angstroms of thickness may be lost (this is an average; the amount varies across the wafer. Depending on the slurry and methods used during CMP, the germanium loss may be more or less.) If the planarization step is performed by an etchback method, only about 400 angstroms of germanium or less may be removed. Depending on the planarization method to be used and the desired final thickness, between about 800 and about 4000 angstroms of undoped germanium 114 is deposited by any conventional method; preferably between about 1500 and about 2500 angstroms; most preferably between about 1800 and about 2200 angstroms. If desired, germanium layer 114 can be lightly doped. Top heavily doped region 116 will be formed in a later implant step, but does not exist yet at this point, and thus is not shown in FIG. 12b.

The germanium just deposited will be patterned and etched to form pillars 300. Pillars 300 should have about the same pitch and about the same width as conductors 200 below, such that each pillar 300 is formed on top of a conductor 200. Some misalignment can be tolerated.

The pillars 300 can be formed using any suitable masking and etching process. For example, photoresist can be deposited, patterned using standard photolithography techniques, and etched, then the photoresist removed. Alternatively, a hard mask of some other material, for example silicon dioxide, can be formed on top of the semiconductor layer stack, with bottom antireflective coating (BARC) on top, then patterned and etched. Similarly, dielectric antireflective coating (DARC) can be used as a hard mask.

The photolithography techniques described in Chen, U.S. application Ser. No. 10/728,436, “Photomask Features with Interior Nonprinting Window Using Alternating Phase Shifting,” filed Dec. 5, 2003; or Chen, U.S. application Ser. No. 10/815,312, Photomask Features with Chromeless Nonprinting Phase Shifting Window,” filed Apr. 1, 2004, both owned by the assignee of the present invention and hereby incorporated by reference, can advantageously be used to perform any photolithography step used in formation of a memory array according to the present invention.

To summarize, the pillars 300 were formed by a method comprising depositing germanium or a germanium alloy layerstack above a substantially planar surface; and patterning and etching the layerstack to form first pillars.

Dielectric material 108 is deposited over and between pillars 300, filling the gaps between them. Dielectric material 108 can be any known electrically insulating material, such as silicon oxide, silicon nitride, or silicon oxynitride. In a preferred embodiment, silicon dioxide is used as the insulating material. The silicon dioxide can be deposited using any known process, such as CVD or HDPCVD.

Next the dielectric material on top of the pillars 300 is removed, exposing the tops of pillars 300 separated by dielectric material 108, and leaving a substantially planar surface. This removal of dielectric overfill and planarization can be performed by any process known in the art, such as CMP or etchback. For example, the etchback techniques described in Raghuram et al. can be used. The resulting structure is shown in FIG. 4b.

Turning to FIG. 4c, in preferred embodiments, heavily doped top regions 116 are formed at this point by ion implantation with a p-type dopant, for example boron or BF₂. The diode described herein has a bottom n-type region and a top p-type region. If preferred, the conductivity types could be reversed. If desired, p-i-n diodes having an n-region on the bottom could be used in one memory level while p-i-n diodes having a p-type region on the bottom could be used in another memory level.

The diodes that reside in pillars 300 were formed by a method comprising depositing a semiconductor layer stack above the first conductors and dielectric fill; and patterning and etching the semiconductor layer stack to form the first diodes.

If dielectric rupture antifuse 118 is to be included, it can be formed by any low-temperature deposition of an appropriate dielectric material. For example, a layer of Al₂O₃ can be deposited at about 150 degrees C. Alternatively the antifuse may be liquid phase deposited silicon dioxide, also a low-temperature process. Suitable methods are described by Nishiguchi et al. in “High quality SiO2 film formation by highly concentrated ozone gas at below 600 C,” Applied Physics Letters 81, pp. 2190-2192 (2002); and by Hsu et al. in “Growth and electrical characteristics of liquid-phase deposited SiO2 on Ge,” Electrochemical and Solid State Letters 6, pp. F9-F11 (2003). Other alternatives include a nitride or oxynitride formed by a low-temperature method. Dielectric rupture antifuse 118 is preferably between about 20 and about 80 angstroms thick, preferably about 50 angstroms thick. In some embodiments, dielectric rupture antifuse 118 may be omitted.

Next a conductive material or stack is deposited to form the top conductors 400. In a preferred embodiment, titanium nitride barrier layer 120 is deposited next, followed by aluminum layer 122 and top titanium nitride barrier layer 124. Top conductors 400 can be patterned and etched as described earlier. Overlying second conductors 400 will preferably extend in a different direction from first conductors 200, preferably substantially perpendicular to them. The resulting structure, shown in FIG. 4c, is a bottom or first story of memory cells. Ideally each top conductor 400 is formed directly aligned with a row of pillars 300. Some misalignment can be tolerated. Each memory level comprises bottom conductors 200, pillars 300, and top conductors 400. Bottom conductors 200 are substantially parallel and extend in a first direction, and top conductors 400 are substantially parallel and extend in a second direction different from the first direction.

Note that in this memory level, for each memory cell, the bottom conductor, the pillar, and the top conductor are each patterned in a separate patterning step.

Additional memory levels can be formed above this first memory level. In some embodiments, conductors can be shared between memory levels; i.e. top conductor 400 would serve as the bottom conductor of the next memory level. In other embodiments, an interlevel dielectric (not shown) is formed above the first memory level of FIG. 4c, its surface planarized, and construction of a second memory level begins on this planarized interlevel dielectric, with no shared conductors.

Deposited germanium, when undoped or doped with n-type dopants and deposited at a relatively low temperature, as described, will generally be amorphous. After all of the memory levels have been constructed, a final relatively low-temperature anneal, for example performed at between about 350 and about 450 degrees C., can be performed to crystallize the germanium diodes; in this embodiment the resulting diodes will be formed of polygermanium. Large batches of wafers, for example 25 wafers or more, can be annealed at a time, maintaining adequate throughput.

Vertical interconnects between memory levels and between circuitry in the substrate are preferably formed as tungsten plugs, which can be formed by any conventional method.

Photomasks are used during photolithography to pattern each layer. Certain layers are repeated in each memory level, and the photomasks used to form them may be reused. For example, a photomask defining the pillars 300 of FIG. 4c may be reused for each memory level. Each photomask includes reference marks used to properly align it. When a photomask is reused, reference marks formed in a second or subsequent use may interfere with the same reference marks formed during a prior use of the same photomask. Chen-et al., U.S. patent application Ser. No. 11/097,496, “Masking of Repeated Overlay and Alignment Marks to Allow Reuse of Photomasks in a Vertical Structure,” filed Mar. 31, 2005, and hereby incorporated by reference, describes a method to avoid such interference during the formation of a monolithic three dimensional memory array like that of the present invention.

### EXAMPLE

### Copper Conductors

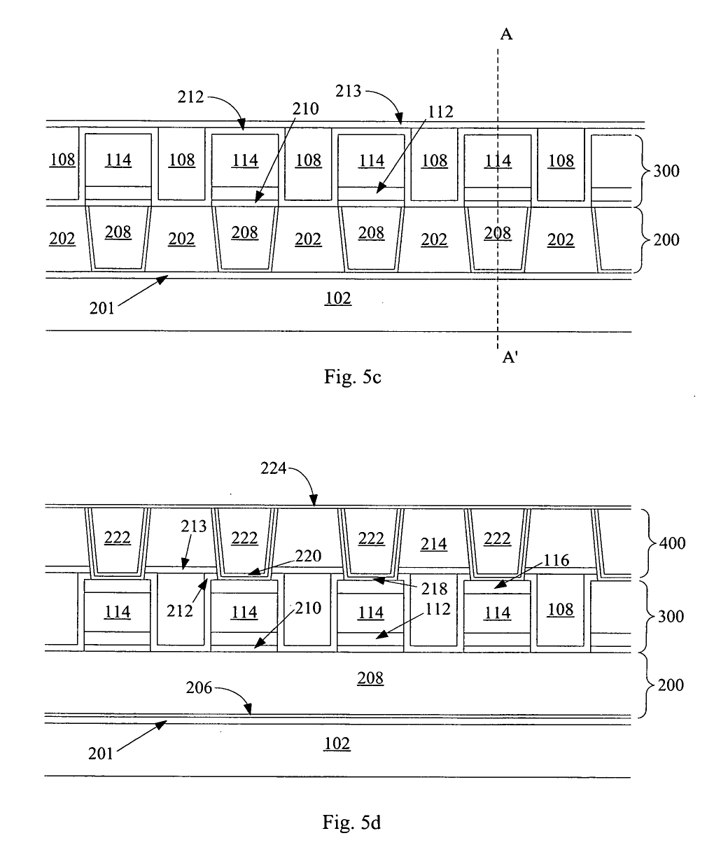

Turning to FIG. 5a, in this embodiment, fabrication begins as before over substrate 100 and insulating layer 102, which may be as described in the previous embodiment.

In preferred embodiments a think layer 201 of, for example, silicon nitride is deposited on insulating layer 102. This layer will serve as an etch stop during the damascene etch to come.

Next a thick layer 202 of a dielectric, for example TEOS, is deposited. Its thickness may be between about 1000 and about 6000 angstroms, preferably about 4000 angstroms. A conventional damascene etch is performed to etch substantially parallel trenches 204. The etch stops on silicon nitride layer 201. A barrier layer 206 of, for example, tantalum nitride, tantalum, tungsten, tungsten nitride, titanium nitride, or any other appropriate material is conformally deposited covering dielectric layer 202 and lining trenches 204.

As shown in FIG. 5b, next copper layer 208 is deposited on barrier layer 206, filling trenches 204. Copper layer 208 is preferably pure copper, though an alloy of copper may be used if desired. A planarization step, for example by CMP, removes overfill of copper 208, coexposing the copper 208 and the dielectric 202, as well as barrier material 206, at a substantially planar surface. Bottom conductors 200 have been formed. The pitch of bottom conductors 200 may be as described in the previous embodiment.

To summarize, bottom conductors 200 were formed by depositing a first dielectric material; etching a plurality of substantially parallel trenches in the dielectric material; depositing copper over the first dielectric material and filling the trenches; planarizing to remove overfill of copper and form a substantially planar surface coexposing the first bottom conductors and the first dielectric material.

Turning to FIG. 5c, a conductive barrier layer 210 is deposited on the planar surface. This barrier layer is preferably tantalum nitride or tantalum, though some other suitable material may be used instead.

Next the germanium or germanium alloy layerstack that will be etched to form the diodes is deposited as in the previous embodiment, including heavily doped n-type germanium layer 112 and undoped germanium layer 114. Germanium or any of the previously-mentioned germanium alloys may be used. As in the previous embodiment, heavily doped p-type germanium layer 116 will be doped by a later implant step, and thus has not yet been formed and is not shown in FIG. 5c.

The germanium just deposited will be patterned and etched to form pillars 300. Tantalum nitride barrier layer 208 will be etched as well, leaving copper layer 208 exposed between the pillars. Pillars 300 should have about the same pitch and about the same width as conductors 200 below, such that each pillar 300 is formed on top of a conductor 200. Some misalignment can be tolerated.

In general, copper must be encapsulated to avoid its diffusion into other materials. A thin layer 212 of an appropriate dielectric barrier material, for example silicon carbide, silicon nitride, a Si—C—O—H film, or some other high-K dielectric should be deposited next, covering dielectric 202 and encapsulating copper 208 in conductors 200. Silicon carbide barrier dielectric 212 will also cover the tops of pillars 300, and, depending on the step coverage of the material, may cover the sidewalls of pillars 300 as well. An oxide 108 or other appropriate gap fill material is deposited, for example by HDPCVD, filling gaps between the pillars 300. Dielectric layer 108 fills past the top of the pillars 300.

Next the dielectric material on top of the pillars 300 is removed, exposing the tops of silicon carbide barrier dielectric 212 on top of pillars 300 separated by dielectric material 108, and leaving a substantially planar surface. This removal of dielectric overfill and planarization can be performed by any process known in the art, such as CMP or etchback. For example, the etchback techniques described in Raghuram et al. can be used. Next silicon nitride etch stop layer 213 is deposited on the planar surface. The resulting structure is shown in FIG. 5c.

The view of FIG. 5d is perpendicular to the view of 5c, along line A-A′. Referring to FIG. 5d, dielectric material 214 is deposited on silicon nitride etch stop layer 213; its thickness is preferably comparable to that of dielectric 202 in which bottom conductors 200 were formed. Next trenches are etched in dielectric 214. The etch will stop at silicon nitride etch stop layer 214. A low-rate etch removes first silicon nitride layer 214, then silicon carbide layer 212, exposing the tops of pillars 300. The ion implantation of a p-type dopant such as boron or BF₂ is preferably performed at this point, forming heavily doped p-type regions 116.

Next a dielectric rupture antifuse 218 is formed, preferably by atomic layer deposition of Al₂O₃, conformally filling the trenches. Alternative methods of forming dielectric rupture antifuse 218, as described in the previous embodiment, may be used instead. Dielectric rupture layer 218 is preferably between about 15 and about 80 angstroms thick, preferably about 50 angstroms thick. In some embodiments dielectric rupture antifuse 218 may be omitted.

Top conductors 400 are formed in the same manner as bottom conductors 200. Barrier layer 220, preferably of tantalum nitride, lines the trenches, and copper layer 222 fills the trenches. A planarization step, for example by CMP, removes overfill of copper, forming top conductors 400 and creating a substantially planar surface. If an interlevel dielectric is to be formed between this memory level and the next, a dielectric barrier layer 224, for example of silicon carbide, can be deposited on this substantially planar surface to encapsulate copper layer 222.

If instead the next memory level is to share top conductors 400, i.e. if top conductors 400 are to serve as the bottom conductors of the next memory level, then a conductive nitride barrier layer such as tantalum nitride can be deposited on the substantially planar surface instead (not shown.) The germanium stack to form the next set of pillars will be deposited next, and fabrication continues as described for pillars 300, with the conductive barrier layer etched with the pillars, deposition of a conformal high-K barrier dielectric over the pillars and the copper, etc.

Vertical interconnects between memory levels and between circuitry in the substrate are preferably formed of copper in a conventional dual damascene process.

Each of the two embodiments described, and the other teachings herein, have taught a method for forming a monolithic three dimensional memory array, the method comprising forming a first memory level above a substrate, the first memory level comprising a first plurality of memory cells, each first memory cell comprising semiconductor material; and monolithically forming a second memory level above the first memory level, wherein during formation of the monolithic three dimensional memory array, processing temperature during formation of the array does not exceed about 500 degrees C. Depending on the crystallization temperature and anneal time selected, processing temperature during formation of such an array will not exceed about 475, 450, 425, 400, 375, or about 350 degrees C.

More specifically, what has been described is a a method for forming a first memory level, the method comprising forming a first plurality of substantially parallel, substantially coplanar rail-shaped bottom conductors extending in a first direction, the first bottom conductors comprising copper or aluminum; forming a first plurality of diodes above the first bottom conductors, the first diodes comprising germanium or a germanium alloy; forming a first plurality of substantially parallel, substantially coplanar rail-shaped top conductors above the first diodes, the first top conductors, the first top conductors extending in a second direction different from the first direction, the first top conductors comprising copper or aluminum, wherein, during formation of the first memory level, processing temperature does not exceed 500 degrees C., or any of the other lower temperatures mentioned.

It is expected that, when compared to silicon diodes or any other polycrystalline diodes, the vertically oriented p-i-n diode formed of polycrystalline germanium or germanium-rich which has been described for use in the present invention will allow relatively higher current flow for an applied read voltage. For example, when a read voltage of about 1 volt is applied between the top and bottom conductors of a memory cell formed according to the present invention, in a programmed cell (in which the antifuse has been ruptured and a low-resistance conductive path has been formed through the diode), it is expected that current greater than about 100 microamps will flow. For example, when a read voltage of about 1 volt is applied, current flow may be between about 100 microamps and 1 milliamp.

A monolithic three dimensional memory array is one in which multiple memory levels are formed above a single substrate, such as a wafer, with no intervening substrates. The layers forming one memory level are deposited or grown directly over the layers of an existing level or levels. In contrast, stacked memories have been constructed by forming memory levels on separate substrates and adhering the memory levels atop each other, as in Leedy, U.S. Pat. No. 5,915,167, “Three dimensional structure memory.” The substrates may be thinned or removed from the memory levels before bonding, but as the memory levels are initially formed over separate substrates, such memories are not true monolithic three dimensional memory arrays.

A monolithic three dimensional memory array formed above a substrate comprises at least a first memory level formed at a first height above the substrate and a second memory level formed at a second height different from the first height. Three, four, eight, or indeed any number of memory levels can be formed above the substrate in such a multilevel array.

The nonvolatile one-time programmable memory cell of the present invention has been described in the context of a monolithic three dimensional memory array, but would be advantageous in any other context requiring low fabrication temperature, for example with certain low-temperature substrates.

Detailed methods of fabrication have been described herein, but any other methods that form the same structures can be used while the results fall within the scope of the invention.

The foregoing detailed description has described only a few of the many forms that this invention can take. For this reason, this detailed description is intended by way of illustration, and not by way of limitation. It is only the following claims, including all equivalents, which are intended to define the scope of this invention.

What is claimed is:

1. A method for forming a monolithic three dimensional memory array, the method comprising:
forming a first memory level above a substrate, the first memory level comprising a first plurality of memory cells, each first memory cell comprising semiconductor material; and
monolithically forming a second memory level above the first memory level, wherein during formation of the monolithic three dimensional memory array,
processing temperature during formation of the array does not exceed about 500 degrees C.

2. The method of claim 1 wherein the processing temperature does not exceed about 450 degrees C.

3. The method of claim 1 wherein the processing temperature does not exceed about 400 degrees C.

4. The method of claim 1 wherein the processing temperature does not exceed about 375 degrees C.

5. The method of claim 1 wherein the processing temperature does not exceed about 350 degrees C.

6. The method of claim 1 wherein the substrate comprises monocrystalline silicon.

7. The method of claim 1 wherein each memory cell comprises a diode, the diode comprising the semiconductor material.

8. The method of claim 7 wherein the semiconductor material is polycrystalline.

9. The method of claim 8 wherein the polycrystalline semiconductor material is germanium or a germanium alloy.

10. The method of claim 1 wherein each memory cell further comprises an antifuse.

11. The method of claim 10 wherein the antifuse comprises an oxide, nitride, or oxynitride layer.

12. The method of claim 1 wherein the first memory level further comprises a first plurality of bottom conductors and a first plurality of top conductors, the first bottom or the first top conductors comprising aluminum or copper.

13. The method of claim 1 wherein the semiconductor comprises first doped semiconductor material having a first conductivity type and second doped semiconductor material having a second conductivity type.

14. A monolithic three dimensional memory array comprising:
a) a first memory level comprising:
i) a first plurality of bottom conductors, the first bottom conductors comprising a first aluminum layer or first copper layer;
ii) a first plurality of pillar-shaped diodes above the first bottom conductors, the first diodes comprising germanium or a germanium alloy; and
iii) a first plurality of top conductors above the first diodes, the first top conductors comprising a second aluminum layer or a second copper layer; and
b) a second memory level monolithically formed above the first memory level.

15. The monolithic three dimensional memory array of claim 14,
wherein the first bottom conductors are substantially parallel and extend in a first direction, and
wherein the first top conductors are substantially parallel and extend in a second direction different from the first direction.

16. The monolithic three dimensional memory array of claim 15 wherein the first bottom or top conductors comprise aluminum and are formed by:
depositing the first aluminum layer; and
patterning and etching the first aluminum layer to form the first bottom or top conductors.

17. The monolithic three dimensional memory array of claim 15 wherein the first bottom or top conductors comprise copper and are formed by a damascene method.

18. A method for forming a first memory level, the method comprising:
forming a first plurality of substantially parallel, substantially coplanar rail-shaped bottom conductors extending in a first direction, the first bottom conductors comprising copper or aluminum;
forming a first plurality of diodes above the first bottom conductors, the first diodes comprising germanium or a germanium alloy;
forming a first plurality of substantially parallel, substantially coplanar rail-shaped top conductors above the first diodes, the first top conductors, the first top conductors extending in a second direction different from the first direction, the first top conductors comprising copper or aluminum,
wherein, during formation of the first memory level, processing temperature does not exceed 500 degrees C.

19. The method of claim 18 wherein, during formation of the first memory level, processing temperature does not exceed 400 degrees C.

20. The method of claim 18 wherein, during formation of the first memory level, processing temperature does not exceed 350 degrees C.

21. The method of claim 18 wherein the step of forming the first bottom conductors comprises:
depositing an aluminum layer;
patterning and etching the aluminum layer to form the first bottom conductors;
depositing a first dielectric material over and between the first bottom conductors; and
planarizing to form a substantially planar surface coexposing the first bottom conductors and the first dielectric material.

22. The method of claim 21 wherein the step of forming the first diodes comprises:
depositing germanium or a germanium alloy layerstack above the substantially planar surface; and
patterning and etching the layerstack to form first pillars.

23. The method of claim 18 wherein the step of forming the first bottom conductor comprises:
depositing a first dielectric material;
etching a plurality of substantially parallel trenches in the dielectric material;
depositing copper over the first dielectric material and filling the trenches;
planarizing to remove overfill of copper and form a substantially planar surface coexposing the first bottom conductors and the first dielectric material.

24. The method of claim 23 wherein the step of forming the first diodes comprises:
depositing germanium or a germanium alloy layerstack above the substantially planar surface; and
patterning and etching the layerstack to form first pillars.

25. The method of claim 18, the method further comprising forming first dielectric rupture antifuses, each disposed between one of the first diodes and one of the first top conductors or between one of the first diodes and one of the first bottom conductors.

26. A nonvolatile one-time programmable memory cell comprising:
a bottom conductor;
a polycrystalline diode above the bottom conductor; and
a top conductor above the diode,
wherein, after the cell has been programmed, when about 1 volt is applied between the top conductor and the bottom conductor, a current flowing through the diode is at least about 100 microamps.

27. The nonvolatile one-time programmable memory cell of claim 26 wherein the diode comprises a semiconductor material, wherein the semiconductor material is germanium or a germanium alloy.

28. The nonvolatile one-time programmable memory cell of claim 27 wherein the germanium alloy is at least 20 atomic percent germanium.

29. The nonvolatile one-time programmable memory cell of claim 27 wherein the germanium alloy is at least 50 atomic percent germanium.

30. The nonvolatile one-time programmable memory cell of claim 27 wherein the germanium alloy is at least 80 atomic percent germanium.

31. The nonvolatile one-time programmable memory cell of claim 26 wherein the bottom conductor or the top conductor comprises an aluminum alloy.

32. The nonvolatile one-time programmable memory cell of claim 26 wherein the bottom conductor or the top conductor comprises a layer consisting essentially of copper or a copper alloy.

33. The nonvolatile one-time programmable memory cell of claim 26 wherein the cell further comprises a dielectric rupture antifuse.

34. The nonvolatile one-time programmable memory cell of claim 33 wherein the dielectric rupture antifuse is arranged in series with the diode.

35. The nonvolatile one-time programmable memory cell of claim 26 wherein the cell is formed above a substrate.

36. The nonvolatile one-time programmable memory cell of claim 35 wherein the substrate comprises monocrystalline silicon.

37. The nonvolatile one-time programmable memory cell of claim 26 wherein the current is between about 100 microamps and about 1 milliamp.

38. A nonvolatile memory cell comprising:
a bottom conductor comprising aluminum or copper;
a pillar comprising a semiconductor material, wherein the semiconductor material is at least 20 atomic percent germanium; and
a top conductor comprising aluminum or copper,
wherein the pillar is disposed between the top conductor and the bottom conductor, and
wherein the semiconductor material is formed in a high-resistance state, and, upon application of a programming voltage, converts to a diode in a low-resistance state.

39. The nonvolatile memory cell of claim 38 wherein the semiconductor material is at least 50 atomic percent germanium.

40. The nonvolatile memory cell of claim 38 wherein the semiconductor material is at least 80 atomic percent germanium.

41. The nonvolatile memory cell of claim 38 wherein the semiconductor material is at least 90 atomic percent germanium.

42. The nonvolatile memory cell of claim 38 wherein the semiconductor material is polycrystalline.

43. The nonvolatile memory cell of claim 38 wherein the diode is a junction diode.

44. The nonvolatile memory cell of claim 43 wherein the diode is a p-i-n diode.

45. A monolithic three dimensional memory array comprising:
a) a first memory level formed above a substrate, the first memory level comprising a plurality of memory cells, each memory cell comprising:
i) a bottom conductor comprising an aluminum alloy;
ii) a pillar comprising a semiconductor material, wherein the semiconductor material is at least 20 atomic percent germanium; and
iii) a top conductor comprising an aluminum alloy,
wherein the pillar is disposed between the top conductor and the bottom conductor, and
wherein the semiconductor material is formed in a high-resistance state, and, upon application of a programming voltage, converts to a diode in a low-resistance state; and
b) a second memory level monolithically formed above the first.

46. The monolithic three dimensional memory array of claim 45 wherein the substrate is monocrystalline silicon.

47. The monolithic three dimensional memory array of claim 45 wherein for each memory cell, the bottom conductor, the pillar, and the top conductor are each patterned in a separate patterning step.

48. The monolithic three dimensional memory array of claim 45 wherein the semiconductor material is at least 50 atomic percent germanium.

49. The monolithic three dimensional memory array of claim 45 wherein the semiconductor material is at least 80 atomic percent germanium.

50. The monolithic three dimensional memory array of claim 45 wherein the semiconductor material is at least 90 atomic percent germanium.

51. The monolithic three dimensional memory array of claim 45 wherein the semiconductor material is polycrystalline.

52. A monolithic three dimensional memory array comprising:
a) a first memory level formed above a substrate, the first memory level comprising:
i) a bottom conductor comprising copper, the bottom conductor formed by a damascene method;
ii) a pillar comprising a semiconductor material, wherein the semiconductor material is at least 20 atomic percent germanium; and
iii) a top conductor comprising copper, the top conductor formed by a damascene method,
wherein the pillar is disposed between the top conductor and the bottom conductor, and
wherein the semiconductor material is formed in a high-resistance state, and, upon application of a programming voltage, converts to a diode in a low-resistance state; and
b) a second memory level monolithically formed above the first.

53. The monolithic three dimensional memory array of claim 52 wherein the substrate is monocrystalline silicon.

54. The monolithic three dimensional memory array of claim 52 wherein the semiconductor material is at least 50 atomic percent germanium.

55. The monolithic three dimensional memory array of claim 52 wherein the semiconductor material is at least 80 atomic percent germanium.

56. The monolithic three dimensional memory array of claim 52 wherein the semiconductor material is at least 90 atomic percent germanium.

57. The monolithic three dimensional memory array of claim 52 wherein the semiconductor material is polycrystalline.

58. A method for forming a monolithic three dimensional memory array, the method comprising:
a) forming a first memory level above a substrate by a method comprising:
i) forming a first plurality of substantially parallel, substantially coplanar bottom conductors, the first bottom conductors comprising copper or an aluminum alloy;
ii) forming a first plurality of diodes above the first bottom conductors, the first diodes comprising germanium or a germanium alloy; and
iii) forming a first plurality of substantially parallel, substantially coplanar top conductors above the first diodes, the first top conductors comprising copper or an aluminum alloy; and
b) monolithically forming a second memory level above the first memory level.

59. The method of claim 58 wherein the step of forming the first bottom conductors comprises:
depositing conductive layer or stack comprising an aluminum alloy layer;
patterning and etching the conductive layer or stack to form the first bottom conductors;
depositing a first dielectric material over and between the first bottom conductors;
planarizing to form a substantially planar surface coexposing tops of the first bottom conductors and the first dielectric material.

60. The method of claim 59 wherein the step of forming the first diodes comprises:
depositing a layerstack of germanium or germanium alloy above the substantially planar surface; and
patterning and etching the layerstack to form first pillars.

61. The method of claim 58 wherein the step of forming the first bottom conductors comprises:
depositing a layer of first dielectric material;
etching a plurality of trenches in the first dielectric material;
depositing copper on the first dielectric material, filling the trenches;
planarizing to form a substantially planar surface coexposing the copper and the first dielectric material.

62. The method of claim 61 wherein the step of forming the first diodes comprises:
depositing a layerstack of germanium or germanium alloy above the substantially planar surface; and
patterning and etching the layerstack to form first pillars.

63. The method of claim 58 wherein the during formation of the memory array the temperature does not exceed about 500 degrees C.

64. The method of claim 58 wherein the during formation of the memory array the temperature does not exceed about 450 degrees C.

65. The method of claim 58 wherein the during formation of the memory array the temperature does not exceed about 400 degrees C.

66. The method of claim 58 wherein the during formation of the memory array the temperature does not exceed about 350 degrees C.

67. The method of claim 58 wherein the first bottom conductors have a pitch, the pitch not exceeding about 180 nm.

68. The method of claim 67 wherein the pitch does not exceed about 150 nm.

69. The method of claim 67 wherein the pitch does not exceed about 120 nm.

70. The method of claim 67 wherein the pitch does not exceed about 90 nm.
